(19) United States
(12) Patent Application Publication
(10) Pub. No.: US 2024/0385522 A1
(43) Pub. Date: Nov. 21, 2024

(54) COMPOSITION FOR REMOVING EDGE BEADS FROM METAL CONTAINING RESISTS, AND METHOD OF FORMING PATTERNS INCLUDING STEP OF REMOVING EDGE BEADS UTILIZING THE COMPOSITION, AND A SYSTEM OF FORMING PATTERNS

(71) Applicant: SAMSUNG SDI CO., LTD., Yongin-si (KR)

(72) Inventors: Taeksoo KWAK, Suwon-si (KR); Si-Kyun PARK, Suwon-si (KR); Hyungrang MOON, Suwon-si (KR); Jongpil HO, Suwon-si (KR); Gyeonghun PARK, Suwon-si (KR); Myoungsoo SONG, Suwon-si (KR); Jin-Hee BAE, Suwon-si (KR); Minsoo KIM, Suwon-si (KR); Seung HAN, Suwon-si (KR); Taeho KIM, Suwon-si (KR); Gyeong Ryeong BAK, Suwon-si (KR)

(21) Appl. No.: 18/610,099

(22) Filed: Mar. 19, 2024

(30) Foreign Application Priority Data
May 15, 2023 (KR) 10-2023-0062597

(51) Int. Cl. G03F 7/11; C07F 7/22; G03F 7/004; H01L 21/027

(52) U.S. Cl. CPC G03F 7/11; C07F 7/2208; G03F 7/0042; H01L 21/0271

(57) ABSTRACT

A composition for removing edge beads from metal-containing resists, and a method of forming patterns including a step of removing edge beads using the composition are provided. The composition for removing edge beads includes an additive including at least one selected from among phosphoric acid, a phosphorous acid-based compound, and a hypophosphorous acid-based compound, and a carboxylic acid-based compound, and an organic solvent, where a mixed weight ratio of the at least one selected from among the phosphoric acid, the phosphorous acid-based compound, and the hypophosphorous acid-based compound to the carboxylic acid-based compound is about 9:1 to about 1.2:1.

### CROSS-REFERENCE TO RELATED APPLICATION

The present application claims priority to and the benefit of Korean Patent Application No. 10-2023-0062597, filed on May 15, 2023, in the Korean Intellectual Property Office, the content of which in its entirety is herein incorporated by reference.

### BACKGROUND

### 1. Field

One or more embodiments of the present disclosure relate to a composition for removing edge beads for reducing metal contamination along a wafer edge, and a method of forming patterns including a step of removing edge beads utilizing the composition.

### 2. Description of Related Art

In recent years, semiconductor manufacturing in the industry has been accompanied by a substantially continuous reduction of critical dimensions, and this dimensional reduction requires or desires new types (kinds) of high-performance photoresist materials and a patterning method that satisfy a demand for processing and patterning with such increasingly smaller features.

Also, with the recent rapid development in the semiconductor industry, a semiconductor device is required or desired to have a relatively fast operation speed and large storage capacity, and in line with this requirement or desire, process technology for improving integration, reliability, and response speed of the semiconductor device is being developed. For example, it is important to accurately control/implant impurities in working regions of a semiconductor substrate (e.g., a silicon substrate) and to interconnect these working regions to form a device and/or an ultra-high-density integrated circuit, which may be achieved by a photolithographic process. In other words, it is important to integrate the photolithographic process including coating a photoresist on the substrate, selectively exposing it to ultraviolet (UV) (including extreme ultraviolet (EUV)), electron beams, X rays, and/or the like, and then, developing it.

For example, in the process of forming a photoresist film, a photoresist composition is coated on a substrate (e.g., a silicon substrate), mainly while rotating the substrate, wherein the photoresist is coated on an edge and rear surface of the substrate, which may cause indentation or pattern defects in the subsequent semiconductor processes such as etching and ion implantation processes. Accordingly, a process of stripping and removing the photoresist coated on the edge and rear surface of the substrate by utilizing a thinner composition, that is, an EBR (edge bead removal) process is performed. The EBR process requires a composition that exhibits excellent or suitable solubility for the photoresist and effectively removes beads and the photoresist remaining on (or with) the substrate and generates no photoresist residue.

### SUMMARY

One or more aspects of embodiments of the present disclosure are directed toward a composition for removing edge beads, and in particular, a composition for removing edge beads that minimizes photoresist residue.

One or more aspects of embodiments of the present disclosure are directed toward a method of forming patterns, in more detail, a method of forming patterns including an edge bead removal step.

Additional aspects will be set forth in part in the description which follows and, in part, will be apparent from the description, or may be learned by practice of the presented embodiments of the disclosure.

A composition for removing edge beads from metal-containing resists according to one or more embodiments of the present disclosure includes:
an additive including at least one selected from among phosphoric acid, a phosphorous acid-based compound, and a hypophosphorous acid-based compound;
a carboxylic acid-based compound; and
an organic solvent,
wherein a mixing weight ratio of the at least one selected from among the phosphoric acid, the phosphorous acid-based compound, and the hypophosphorous acid-based compound to the carboxylic acid-based compound may be about 9:1 to about 1.2:1.

In one or more embodiments, the mixing weight ratio of the at least one selected from among the phosphoric acid, the phosphorous acid-based compound, and the hypophosphorous acid-based compound to the carboxylic acid-based compound may be about 9:1 to about 6:4.

The composition for removing edge beads from metal-containing resists may include about 0.01 wt % to about 50 wt % of the additive and about 50 wt % to about 99.99 wt % of the organic solvent.

In one or more embodiments, the at least one selected from among the phosphoric acid, the phosphorous acid-based compound, and the hypophosphorous acid-based compound may be included in an amount of about 0.005 to about 10 wt % based on 100 wt % of the composition for removing edge beads from metal-containing resists.

The carboxylic acid-based compound may be included in an amount of about 0.001 to about 5 wt % based on 100 wt % of the composition for removing edge beads from metal-containing resists.

The phosphorous acid-based compound may be phosphonic acid, methyl phosphonic acid, ethyl phosphonic acid, butyl phosphonic acid, hexyl phosphonic acid, n-octyl phosphonic acid, tetradecyl phosphonic acid, octadecyl phosphonic acid, phenyl phosphonic acid, vinyl phosphonic acid, aminomethyl phosphonic acid, methylenediamine tetra methylene phosphonic acid, ethylenediamine tetra methylene phosphonic acid, 1-amino 1-phosphonooctyl phosphonic acid, etidronic acid, 2-aminoethyl phosphonic acid, 3-aminopropyl phosphonic acid, 6-hydroxyhexyl phosphonic acid, decyl phosphonic acid, methylene diphosphonic acid, nitrilotrimethylene triphosphonic acid, 1H, 1H, 2H, 2H-perfluorooctanephosphonic acid, or a combination thereof.

The hypophosphorous acid-based compound may be phosphinic acid, phenylphosphinic acid, diphenylphosphinic acid, bis(4-methoxyphenyl)phosphinic acid, bis(hydroxymethyl)phosphinic acid, p-(3-aminopropyl)-p-butylphosphinic acid, or a combination thereof.

The carboxylic acid-based compound may be at least one selected from among acetic acid, formic acid, propionic acid, butyric acid, valeric acid, caproic acid, and benzoic acid.

A moisture (e.g., water) content (e.g., amount) of the composition for removing edge beads may be less than or equal to about 1,000 ppm.

A metal compound included in the metal-containing resists may include at least one of an organic oxy group-containing tin compound or an organic carbonyloxy group-containing tin compound.

The metal compound included in the metal-containing resists may be represented by Chemical Formula 1.

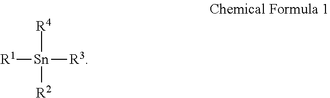

In Chemical Formula 1,
R¹ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted (C6 to C30 aryl) alkyl group, and L^{a}-O—R^{a} (wherein L^{a} is a substituted or unsubstituted C1 to C20 alkylene group and R^{a} is a substituted or unsubstituted C1 to C20 alkyl group),
R² to R⁴ may each independently be selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted (C6 to C30 aryl) alkyl group, —OR^{b}, and —OC(═O)R^{c},
at least one selected from among R² to R⁴ may each independently be selected from among —OR^{b} and —OC(═O)R^{c},
R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

A method of forming patterns according to one or more embodiments includes coating a metal-containing resist composition on a substrate; coating the composition for removing edge beads from metal-containing resists along the edges of the substrate; drying and heating a resultant coating to form a metal-containing photoresist film on the substrate; exposing the metal-containing photoresist film; and developing the metal-containing photoresist film.

The composition for removing edge beads from metal-containing resists according to one or more embodiments reduces the metal-based contamination inherent in the metal-containing resists and removes the photoresist coated on the edge and the rear surface of the substrate, thereby satisfying requirements of processing and patterning of smaller features.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a schematic view of a photoresist coating apparatus according to one or more embodiments of the present disclosure.

FIG. 2 is an image of a photoresist thin film measured after spraying the composition for removing edge beads on a photoresist thin film on a silicon wafer with a profiler equipment according to one or more embodiments of the present disclosure.

FIG. 3 is a schematic view of a hump shown in FIG. 2.

### DETAILED DESCRIPTION OF THE EMBODIMENTS

The present disclosure may be modified in many alternate forms, and thus specific embodiments will be exemplified in the drawing and described in more detail. It should be understood, however, that it is not intended to limit the present disclosure to the particular forms disclosed, but rather, is intended to cover all modifications, equivalents, and alternatives falling within the spirit and scope of the present disclosure.

Hereinafter, embodiments of the present disclosure are described in more detail with reference to the accompanying drawings. In the following description of the present disclosure, the well-suitable functions or constructions will not be described in order to clarify the present disclosure.

In order to clearly illustrate the present disclosure, the unrelated description and relationships are not provided, and throughout the disclosure, the same or similar configuration elements are designated by the same reference numerals. Also, because the size and thickness of each configuration shown in the drawing are illustratively shown for better understanding and ease of description, the present disclosure is not necessarily limited thereto.

In the drawings, the thickness of layers, films, panels, regions, etc., may be exaggerated for clarity. In the drawings, the thickness of a part of layers or regions, etc., may be exaggerated for clarity. It will be understood that when an element such as a layer, film, region, or substrate is referred to as being “on” another element, it may be directly on the other element or intervening elements may also be present. In contrast, when an element is referred to as being “directly on” another element, there are no intervening elements present therebetween.

In the present disclosure, “substituted” refers to replacement of hydrogen by deuterium, a halogen, a hydroxyl group, an amino group, a substituted or unsubstituted C1 to C30 amine group, a nitro group, a substituted or unsubstituted C1 to C40 silyl group, a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a cyano group. “Unsubstituted” refers to that hydrogen remains as hydrogen without being replaced by another substituent.

In the present disclosure, the term “alkyl group” refers to a linear or branched aliphatic hydrocarbon group, unless otherwise defined. The alkyl group may be a “saturated alkyl group” that does not contain any double or triple bonds.

The alkyl group may be a C1 to C20 alkyl group. In one or more embodiments, the alkyl group may be a C1 to C10 alkyl group or a C1 to C6 alkyl group. For example, a C1 to C5 alkyl group refers to that the alkyl chain contains 1 to carbon atoms, and may be selected from among methyl, ethyl, propyl, iso-propyl, n-butyl, iso-butyl, sec-butyl, and t-butyl.

Non-limiting examples of the alkyl group may include a methyl group, an ethyl group, a propyl group, an isopropyl group, a butyl group, an isobutyl group, a t-butyl group, a pentyl group, or a hexyl group, etc.

In the present disclosure, when a definition is not otherwise provided, the term “cycloalkyl group” refers to a monovalent cyclic aliphatic hydrocarbon group.

The cycloalkyl group refers to a cyclopropyl group, a cyclobutyl group, a cyclopentyl group, or a cyclohexyl group, etc.

In the present disclosure, when a definition is not otherwise provided, the term “alkenyl group” may be a linear or branched aliphatic hydrocarbon group, and refers to an aliphatic unsaturated alkenyl group containing one or more carbon-carbon double bonds.

In the present disclosure, when a definition is not otherwise provided, the term “alkynyl group” may be a linear or branched aliphatic hydrocarbon group, and refers to an unsaturated alkynyl group containing one or more carbon-carbon triple bonds.

In the present disclosure, “aryl group” refers to a substituent in which all elements of a cyclic substituent have p-orbitals, and these p-orbitals form a conjugate and may include monocyclic or fused ring polycyclic (i.e., rings that share adjacent pairs of carbon atoms) functional groups.

For example, the substituted or unsubstituted C6 to C30 aryl group may be a substituted or unsubstituted phenyl group, a substituted or unsubstituted naphthyl group, a substituted or unsubstituted anthracenyl group, a substituted or unsubstituted phenanthrenyl group, a substituted or unsubstituted naphthacenyl group, a substituted or unsubstituted pyrenyl group, a substituted or unsubstituted biphenyl group, a substituted or unsubstituted p-terphenyl group, a substituted or unsubstituted m-terphenyl group, a substituted or unsubstituted o-terphenyl group, a substituted or unsubstituted chrysenyl group, a substituted or unsubstituted benzophenanthrenyl group, a substituted or unsubstituted triphenylene group, a substituted or unsubstituted perylenyl group, a substituted or unsubstituted fluorenyl group, a substituted or unsubstituted indenyl group, or a combination thereof, but embodiments of the present disclosure are not limited thereto.

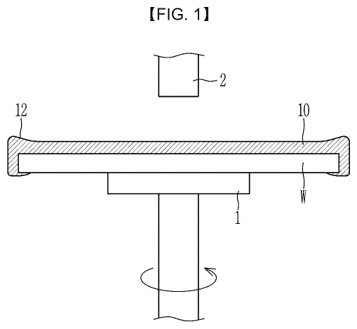

FIG. 1 is a schematic view showing a photoresist coating apparatus according to one or more embodiments.

Referring to FIG. 1, a substrate support portion 1 on which a substrate W is placed is equipped therewith, and the substrate support portion 1 includes a spin chuck or a spin coater.

The substrate support portion 1 rotates in a first direction at a set or predetermined rotation speed to provide a centrifugal force to the substrate W. A spray nozzle 2 may be positioned on the substrate support portion 1 but located off (e.g., away) an upper portion of the substrate W in the atmospheric region so that the spray nozzle may be moved toward the upper portion of the substrate W and spray a photoresist solution 10 in a spraying step. Accordingly, the photoresist solution 10 is coated on a surface (e.g., an upper surface) of the substrate W by the centrifugal force. Herein, the photoresist solution 10 supplied to the center of the substrate W is coated while spreading to the edge of the substrate W by the centrifugal force, wherein a portion of photoresist solution 10 moves to side surfaces of the substrate W and a lower surface of the edge of the substrate.

In one or more embodiments, in the coating process, the photoresist solution 10 may be coated mainly in a spin coating method, wherein a set or predetermined amount of the photoresist solution 10 with viscosity is supplied to a center portion of the substrate W and gradually spreads toward the edge of the substrate W by the centrifugal force. Accordingly, a photoresist film is evenly formed by a rotational speed of the substrate support portion.

In one or more embodiments, this rotation evaporates a solvent from the photoresist solution and thereby gradually increases the viscosity, resulting in making a relatively large amount of the photoresist accumulated on the edge of the substrate (e.g., forming edge beads) by the action of surface tension and, severely, even onto the lower surface of the edge of the substrate, which is referred to as edge beads 12 in the present disclosure.

Hereinafter, a composition for removing edge beads from metal-containing resists according to one or more embodiments is described in more detail. In the present disclosure, the term “resist” may be interchangeable with the term “photoresist.”

The composition for removing edge beads from metal-containing resists according to one or more embodiments of the present disclosure may include an additive includes:
at least one selected from among a phosphoric acid, a phosphorous acid-based compound, and a hypophosphorous acid-based compound;
a carboxylic acid-based compound; and
an organic solvent,
wherein a mixed weight ratio of the at least one selected from among the phosphoric acid, the phosphorous acid-based compound, and the hypophosphorous acid-based compound to the carboxylic acid-based compound may be about 9:1 to about 1.2:1.

By further adding the carboxylic acid-based compound to the at least one selected from among the phosphoric acid, the phosphorous acid-based compound, and the hypophosphorous acid-based compound in the composition, metal-containing resists, for example, undesired metal residues, such as tin-based metal residues, may be more effectively removed.

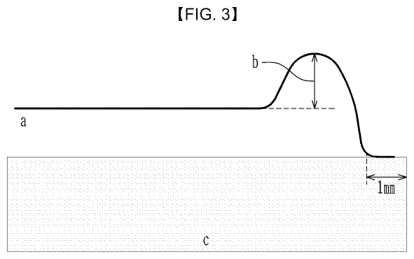

In one or more embodiments, it may minimize or reduce film quality deformation of the photoresist by minimizing or reducing humps that may cause cracks or peeling. As illustrated in FIG. 3, the hump (b) refers to that a film thickness increase (ΔThickness) occurs at the boundary of a resist (a) on a Si substrate (c) with the removed portion after the edge beads are removed.

For example, in some embodiments, the mixed weight ratio of the at least one selected from among the phosphoric acid, the phosphorous acid-based compound, and the hypophosphorous acid-based compound to the carboxylic acid-based compound may be about 9:1 to about 6:4.

In one or more embodiments, the composition for removing edge beads of a metal-containing resist may include about 0.01 wt % to about 50 wt % of the additive and about 50 wt % to about 99.99 wt % of an organic solvent.

In some embodiments, the additive may be included in an amount of about 0.05 wt % to about 50 wt %, about 0.1 wt % to about 50 wt %, about 0.1 wt % to about 40 wt %, about 0.1 wt % to about 30 wt %, about 0.1 wt % to about 20 wt %, or about 0.1 wt % to about 10 wt %.

In some embodiments, the organic solvent may be included in an amount of about 50 wt % to about 99.95 wt %, about 50 wt % to about 99.9 wt %, about 60 wt % to about 99.9 wt %, about 70 wt % to about 99.9 wt %, about 80 wt % to about 99.9 wt %, or about 90 wt % to about 99.9 wt %.

In one or more embodiments, the at least one selected from among the phosphoric acid, the phosphorous acid-based compound, and the hypophosphorous acid-based compound may be included in an amount of about 0.005 wt % to about 10 wt % of based on about 100 wt % of the composition for removing edge beads of a metal-containing resist.

In some embodiments, the at least one selected from among the phosphoric acid, the phosphorous acid-based compound, and the hypophosphorous acid-based compound may be included in an amount of about 0.01 wt % to about 5 wt %, about 0.1 wt % to about 5 wt %, or about 0.5 wt % to about 3 wt %, based on about 100% by weight of the composition for removing edge beads of a metal-containing resist.

In one or more embodiments, the carboxylic acid-based compound may be included in an amount of about 0.001 wt % to about 5 wt % based on about 100% by weight of the composition for removing edge beads of a metal-containing resist.

In some embodiments, of the carboxylic acid-based compound may be included in an amount of about 0.01 wt % to about 5 wt %, about 0.1 wt % to about 5 wt %, or about 0.1 wt % to about 2 wt %, based on about 100% by weight of the composition for removing edge beads of a metal-containing resist.

The phosphorous acid-based compound may be phosphonic acid, methyl phosphonic acid, ethyl phosphonic acid, butyl phosphonic acid, hexyl phosphonic acid, n-octyl phosphonic acid, tetradecyl phosphonic acid, octadecyl phosphonic acid, phenyl phosphonic acid, vinyl phosphonic acid, aminomethyl phosphonic acid, methylenediamine tetra methylene phosphonic acid, ethylenediamine tetra methylene phosphonic acid, 1-amino 1-phosphonooctyl phosphonic acid, etidronic acid, 2-aminoethyl phosphonic acid, 3-aminopropyl phosphonic acid, 6-hydroxyhexyl phosphonic acid, decyl phosphonic acid, methylene diphosphonic acid, nitrilotrimethylene triphosphonic acid, 1H, 1H, 2H, 2H-perfluorooctanephosphonic acid, or a combination thereof.

The hypophosphorous acid-based compound may be phosphinic acid, phenylphosphinic acid, diphenylphosphinic acid, bis(4-methoxyphenyl)phosphinic acid, bis(hydroxymethyl)phosphinic acid, p-(3-aminopropyl)-p-butyl phosphinic acid, or a combination thereof.

The carboxylic acid-based compound may be at least one selected from among acetic acid, formic acid, propionic acid, butyric acid, valeric acid, caproic acid, and benzoic acid.

In some embodiments, a water content (e.g., amount) of the composition for removing edge beads of a metal-containing resists may be less than or equal to about 1,000.

When the moisture (e.g., water) content (e.g., amount) in the composition exceeds about 1,000 ppm, film quality deformation of the photoresist may occur due to hydration in the photoresist contact portion.

The organic solvent included in the composition for removing edge beads from metal-containing resists according to one or more embodiments may be, for example, propylene glycol methyl ether (PGME), propylene glycol methyl ether acetate (PGMEA), propylene glycol butyl ether (PGBE), ethylene glycol methyl ether, diethylglycolethylmethylether, dipropylglycoldimethylether, ethanol, 2-butoxyethanol, n-propanol, isopropanol, n-butanol, isobutanol, hexanol, ethylene glycol, propylene glycol, heptanone, propylene carbonate, butylene carbonate, diethyl ether, dibutyl ether, ethyl acetate, methyl 3-methoxypropionate, ethyl 3-ethoxypropionate, diisopentyl ether, xylene, acetone, methylethylketone, methylisobutylketone, tetrahydrofuran, dimethylsulfoxide, dimethyl formamide, acetonitrile, diacetone alcohol, 3,3-dimethyl-2-butanone, N-methyl-2-pyrrolidone, dimethyl acetamide, cyclohexanone methyl-2-hydroxy-2-methylpropanoate (HBM), gamma butyrolactone (GBL), 1-butanol (n-butanol), ethyl lactate (EL), diene butylether (DBE), diisopropyl ether (DIAE), acetylacetone, n-butylactate, 4-methyl-2-pentenol (or referred to as methyl isobutyl carbinol (MIBC)), 1-methoxy-2-propanol, 1-ethoxy-2-propanol, toluene, xylene, methylethylketone, cyclopentanone, cyclohexanone, 2-hydroxyethyl propionate, 2-hydroxy-2-methylethyl propionate, ethoxyethyl acetate, hydroxyethyl acetate, 2-hydroxy-3-methylmethyl butanoate, 3-methoxymethyl propionate, 3-methoxyethyl propionate, 3-ethoxyethyl propionate, 3-ethoxymethyl propionate, methyl pyruvate, ethyl pyruvate, ethyl acetate, butyl acetate, ethyl lactate, butyl lactate, methyl-2-hydroxyisobutyrate, methoxy benzene, n-butyl acetate, 1-methoxy-2-propyl acetate, methoxyethoxy propionate, ethoxyethoxy propionate, or a mixture thereof, but embodiments of the present disclosure are not limited thereto.

The composition for removing edge beads from metal-containing resists according to the present disclosure may be effective in removing metal-containing resists, for example, undesired metal residues such as tin-based metal residues.

In the case (e.g., embodiments) of including other additives to be described later, the organic solvent may be included in a balance amount excluding the included additive components.

In one or more embodiments, the composition for removing edge beads from metal-containing resists may further include at least one other additive selected from among a surfactant, a dispersant, a moisture absorbent, and a coupling agent.

The metal compound included in the metal-containing resists (i.e., photoresist) may include at least one of an organic oxy group-containing tin compound or an organic carbonyloxy group-containing tin compound.

For example, in one or more embodiments, the metal compound included in the metal-containing resists may be represented by Chemical Formula 1.

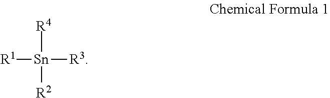

In Chemical Formula 1,
R¹ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted (C6 to C30 aryl) alkyl group, and L^{a}-O—R^{a} (wherein L^{a} is a substituted or unsubstituted C1 to C20 alkylene group and R^{a} is a substituted or unsubstituted C1 to C20 alkyl group),
R² to R⁴ may each independently be selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted (C6 to C30 aryl) alkyl group, —OR^{b}, and —OC(═O)R^{c},
at least one selected from among R² to R⁴ may each independently be selected from among —OR^{b} and —OC(═O)R^{c},
R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

For example, in some embodiments, the metal compound included in the metal-containing resists may be at least one selected from among an alkyloxy group-containing tin compound and an alkylcarbonyloxy group-containing tin compound.

According to one or more embodiments of the present disclosure, a method of forming patterns may include the step of removing edge beads utilizing the composition for removing edge beads from metal-containing resists. For example, in one or more embodiments, the manufactured pattern may be a photoresist pattern. In some embodiments, it may be a negative-type or kind photoresist pattern.

The method of forming patterns according to one or more embodiments may include coating a metal-containing resist composition on a substrate; coating (e.g., applying) the composition for removing edge beads from metal-containing resists along edges of the substrate; drying and heating a resultant coating to form a metal-containing photoresist film on the substrate; exposing the metal-containing photoresist film; and developing the metal-containing photoresist film to form a resist pattern.

First, the forming of patterns utilizing the metal-containing resist composition may include coating the metal-containing resist composition on the substrate. In one or more embodiments, the forming of patterns may include coating the metal-containing resist composition on the substrate on which a thin film is formed by spin coating, slit coating, inkjet printing, etc., and drying the coated metal-containing resist composition to form a photoresist film. The metal-containing resist composition may include a tin-based compound, for example, the tin-based compound may include at least one of an organic oxy group-containing tin compound or an organic carbonyloxy group-containing tin compound.

For example, in some embodiments, the metal compound included in the metal-containing resist is represented by Chemical Formula 1.

Subsequently, the composition for removing edge beads from metal-containing resists is coated. In one or more embodiments, the composition for removing edge beads from metal-containing resists along the edge of the substrate may be coated (e.g., applied) while rotating the substrate at an appropriate or suitable speed (e.g., 500 rpm or more).

Subsequently, a first heat treatment process of heating the substrate on which the photoresist film is formed is performed. The first heat treatment process may be performed at a temperature of about 80° C. to about 120° C., and in this process, the solvent is evaporated and the photoresist film may be more firmly adhered to the substrate.

And then the photoresist film is selectively exposed.

For example, examples of light that may be utilized in the exposure process may include not only light having a short wavelength such as i-line (wavelength 365 nm), KrF excimer laser (wavelength 248 nm), or ArF excimer laser (wavelength 193 nm), but also EUV (light having a high energy wavelength such as EUV (Extreme UltraViolet, wavelength 13.5 nm), or E-Beam (electron beam), etc.

For example, the light for exposure according to some embodiments may be short-wavelength light having a wavelength range of about 5 nm to about 150 nm, or light having a high energy wavelength such as EUV (Extreme UltraViolet, wavelength 13.5 nm), E-Beam (electron beam), etc.

In the step of forming the photoresist pattern, a negative-type or kind pattern may be formed.

The exposed region of the photoresist film has a solubility different from that of the unexposed region of the photoresist film as a polymer is formed in the exposed region by a crosslinking reaction such as condensation between organometallic compounds.

Then, a second heat treatment process is performed on the substrate. The second heat treatment process may be performed at a temperature of about 90° C. to about 200° C. By performing the second heat treatment process, the exposed region of the photoresist film becomes difficult to be dissolved in a developer.

The developing step may be specifically performed by dissolving and removing the photoresist film corresponding to the unexposed region utilizing an organic solvent such as 2-heptanone, to complete the photoresist pattern corresponding to a negative tone image.

The developer utilized in the method of forming patterns according to one or more embodiments may be an organic solvent, for example, ketones such as methyl ethyl ketone, acetone, cyclohexanone, and/or 2-haptanone, alcohols such as 4-methyl-2-propanol, 1-butanol, isopropanol, 1-propanol, and/or methanol, esters such as propylene glycol monomethyl ether acetate, ethyl acetate, ethyl lactate, n-butyl acetate, butyrolactone, aromatic compounds such as benzene, xylene, and/or toluene, or a combination thereof.

As described above, the photoresist pattern formed by exposure to light having a wavelength such as i-line (wavelength 365 nm), KrF excimer laser (wavelength 248 nm), or ArF excimer laser (wavelength 193 nm), EUV (Extreme UltraViolet; wavelength 13.5 nm), or light having high energy such as an E-beam (electron beam) may have a thickness width of about 5 nm to about 100 nm. For example, in one or more embodiments, the photoresist pattern may be formed to have a thickness width of 5 nm to 90 nm, 5 nm to 80 nm, 5 nm to 70 nm, 5 nm to 60 nm, 5 nm to 50 nm, 5 nm to 40 nm, 5 nm to 30 nm, or 5 nm to 20 nm.

In one or more embodiments, the photoresist pattern may have a pitch having a half-pitch of less than or equal to about 50 nm, for example less than or equal to 40 nm, for example less than or equal to 30 nm, for example less than or equal to 20 nm, or for example less than or equal to 15 nm and a line width roughness of less than or equal to about 10 nm, less than or equal to about 5 nm, less than or equal to about 3 nm, or less than or equal to about 2 nm.

Hereinafter, the present disclosure will be described in more detail through examples relating to the preparation of the composition for removing edge beads from metal-containing resists. However, the technical features of the present disclosure are not limited by the following examples.

### Examples 1 to 3 and Comparative Examples 1 to 4: Preparation of Composition for Removing Edge Beads

The additives and the solvent according to each composition shown in Table 1 were mixed and, and completely or substantially dissolved by shaking at room temperature (25° C.). Thereafter, the final composition for removing edge beads was obtained by passing through a filter made of PTFE having a pore size of 1 μm.

### Preparation Example: Preparation of Organometal-Containing Photoresist Composition

Photoresist compositions were prepared by dissolving an organometallic compound with a structural unit represented by Chemical Formula C in 4-methyl-2-pentanol (MIBC) at a concentration of 1 wt % and filtering the solution with a 0.1 μm PTFE syringe filter.

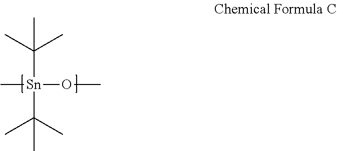

### Evaluation 1: Evaluation of Sn Residual Amount

Onto a 6-inch silicon wafer, 2.0 mL of the organometallic compound-containing photoresist composition according to the preparation example was put and then, allowed to stand for 20 seconds and spin-coated at 1500 rpm for 30 seconds. Subsequently, a coating film obtained through a heat treatment at 200° C. for 60 seconds was measured with respect to a thickness in an ellipsometry method. Onto the wafer on which the coating film was formed, 10 mL of one of the compositions for removing edge beads according to Examples 1 to 3 and Comparative Examples 1 to 4 was put along an edge thereof and spin-coated for 5 seconds and then, dried, while rotating at 1,500 rpm. Subsequently, a film obtained through a heat treatment at 150° C. for 60 seconds was remeasured with respect to a residual amount of Sn through a vapor phase decomposition—inductively coupled plasma—mass spectrometry (VPD ICP-MS) analysis, and the results are shown in Table 1.

### Evaluation 2: Evaluation of Hump Characteristics

Onto a 6-inch silicon wafer, 2.0 mL of the organometallic compound-containing photoresist composition according to the preparation example was put and then, allowed to stand for 20 seconds and spin-coated at 1500 rpm for 30 seconds. Subsequently, one of the compositions for removing edge beads according to Examples 1 to 3 and Comparative Examples 1 to 4 prepared as shown in Table 1 was sprayed for 5 seconds at a flow rate of 10 mL/min from the top of the 1 mm point from the outer periphery of the wafer.

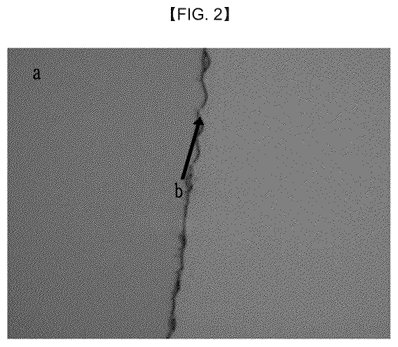

FIG. 2 is an image of a photoresist thin film measured after spraying the composition for removing edge beads on a photoresist thin film on a silicon wafer with a profiler equipment.

FIG. 3 is a schematic view of a hump shown in FIG. 2.

Referring to FIG. 2 and FIG. 3, hump refers to ΔThickness (Hump) generated by convex ends of a photoresist thin film containing an organic metal compound after spraying the compositions for removing edge beads from metal-containing resists, and ΔThickness (Hump) values measured with Tencor's Profiler P17OF facility are shown in Table 1.

TABLE 1

| | | | Residual Sn | |
|---|---|---|---|---|
| | Compositions for removing edge beads | | Amount | |
| | from metal-containing resists | | (×10¹⁰ | Hump (Å) |
| | Additive (wt %) | Solvent (wt %) | atoms/cm²) | (Δ Thickness) |
| Example 1 | vinylphosphonic acid (1)/ | PGMEA (98.5) | 12000 | 810 |
| | propionic acid (0.5) | | | |
| Example 2 | phosphonic acid (1.2)/ | MIBC (98) | 8300 | 900 |
| | acetic acid (0.8) | | | |
| Example 3 | phosphinic acid (1.2)/ | PGMEA (68.6) | 14000 | 910 |
| | formic acid (0.8) | MIBC (29.4) | | |
| Comparative | phosphonic acid (1.2) | MIBC (98.8) | 16000 | 989 |
| Example 1 | | | | |
| Comparative | phosphinic acid (2) | PGMEA (68.6) | 20000 | 1100 |
| Example 2 | | MIBC (29.4) | | |
| Comparative | acetic acid (2) | PGMEA (98) | 43000 | 3500 |
| Example 3 | | | | |
| Comparative | acetic acid (40) | PGMEA (60) | 33000 | 2100 |
| Example 4 | | | | |

Referring to Table 1, the compositions for removing the edge beads from metal-containing resists according to Examples 1 to 3 each exhibited more improved metal removal effect compared with the compositions for removing the edge beads from metal-containing resists according to Comparative Examples 1 to 4, and further promoted reduction of residual metals.

In addition, the compositions for removing edge beads from metal-containing resists according to Examples 1 to 3 each had excellent or suitable metal removal effects compared to the compositions for removing edge beads from metal-containing resists according to Comparative Examples 1 to 4, and the low humps were measured.

Herein, it should be understood that terms such as “comprise(s),” “include(s),” or “have/has” are intended to designate the presence of an embodied feature, number, step, element, or a combination thereof, but it does not preclude the possibility of the presence or addition of one or more other features, number, step, element, or a combination thereof.

As utilized herein, the singular forms “a,” “an,” and “the” are intended to include the plural forms as well, unless the context clearly indicates otherwise. Further, the utilization of “may” when describing embodiments of the present disclosure may refer to “one or more embodiments of the present disclosure”. Further, as used herein, the term “and/or” includes any and all combinations of one or more of the associated listed items. The “/” utilized herein may be interpreted as “and” or as “or” depending on the situation. Expressions such as “at least one of,” “one of,” and “selected from,” when preceding a list of elements, modify the entire list of elements and do not modify the individual elements of the list. For example, “at least one of a, b, or c”, “at least one of a, b, and/or c”, “at least one selected from a, b, and c”, “at least one selected from among a to c”, etc. may indicate only a, only b, only c, both (e.g., simultaneously) a and b, both (e.g., simultaneously) a and c, both (e.g., simultaneously) b and c, all of a, b, and c, or variations thereof.

In the present disclosure, although the terms “first,” “second,” etc., may be utilized herein to describe one or more elements, components, regions, and/or layers, these elements, components, regions, and/or layers should not be limited by these terms. These terms are only utilized to distinguish one component from another component.

As utilized herein, the terms “substantially,” “about,” and similar terms are used as terms of approximation and not as terms of degree, and are intended to account for the inherent deviations in measured or calculated values that would be recognized by those of ordinary skill in the art.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A patten forming system or device, and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Hereinbefore, the certain embodiments of the present disclosure have been described and illustrated, however, it is apparent to a person with ordinary skill in the art that the present disclosure is not limited to the embodiment as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure and equivalents thereof.

### REFERENCE NUMERALS AND SYMBOLS

| | |
|---|---|
| 1: | substrate support portion |
| 2: | spray nozzle |
| 10: | photoresist solution |
| 12: | edge bead |
| a: | resist |
| b: | Hump (Δ Thickness) |
| c: | Si substrate |

What is claimed is:

1. A composition for removing edge beads from metal-containing resists, the composition comprising
an additive comprising at least one selected from among phosphoric acid, a phosphorous acid-based compound, and a hypophosphorous acid-based compound;
a carboxylic acid-based compound; and
an organic solvent,
wherein a mixed weight ratio of the at least one selected from among the phosphoric acid, the phosphorous acid-based compound, and the hypophosphorous acid-based compound to the carboxylic acid-based compound is about 9:1 to about 1.2:1.

2. The composition of claim 1, wherein
the mixing weight ratio of the at least one selected from among the phosphoric acid, the phosphorous acid-based compound, and the hypophosphorous acid-based compound to the carboxylic acid-based compound is about 9:1 to about 6:4.

3. The composition of claim 1, wherein
the composition comprises about 0.01 wt % to about 50 wt % of the additive, and about 50 wt % to about 99.99 wt % of the organic solvent.

4. The composition of claim 1, wherein
the at least one selected from among the phosphoric acid, the phosphorous acid-based compound, and the hypophosphorous acid-based compound is comprised in an amount of about 0.005 to about 10 wt % based on 100 wt % of the composition.

5. The composition of claim 1, wherein
the carboxylic acid-based compound is comprised in an amount of about 0.001 wt % to about 5 wt % based on 100 wt % of the composition.

6. The composition of claim 1, wherein
the phosphorous acid-based compound is phosphonic acid, methyl phosphonic acid, ethyl phosphonic acid, butyl phosphonic acid, hexyl phosphonic acid, n-octyl phosphonic acid, tetradecyl phosphonic acid, octadecyl phosphonic acid, phenyl phosphonic acid, vinyl phosphonic acid, aminomethyl phosphonic acid, methylenediamine tetra methylene phosphonic acid, ethylenediamine tetra methylene phosphonic acid, 1-amino 1-phosphonooctyl phosphonic acid, etidronic acid, 2-aminoethyl phosphonic acid, 3-aminopropyl phosphonic acid, 6-hydroxyhexyl phosphonic acid, decyl phosphonic acid, methylene diphosphonic acid, nitrilotrimethylene triphosphonic acid, 1H, 1H, 2H, 2H-perfluorooctanephosphonic acid, or a combination thereof.

7. The composition of claim 1, wherein
the hypophosphorous acid-based compound is of phosphinic acid, phenylphosphinic acid, diphenylphosphinic acid, bis(4-methoxyphenyl)phosphinic acid, bis(hydroxymethyl)phosphinic acid, p-(3-aminopropyl)-p-butylphosphinic acid, or a combination thereof.

8. The composition of claim 1, wherein
the carboxylic acid-based compound is at least one selected from among acetic acid, formic acid, propionic acid, butyric acid, valeric acid, caproic acid, and benzoic acid.

9. The composition of claim 1, wherein
a moisture amount of the composition is less than or equal to about 1,000 ppm.

10. The composition of claim 1, wherein
a metal compound comprised in the metal-containing resists comprises at least one of an organic oxy group-containing tin compound or an organic carbonyloxy group-containing tin compound.

11. The composition of claim 1, wherein
a metal compound comprised in the metal-containing resists is represented by Chemical Formula 1: 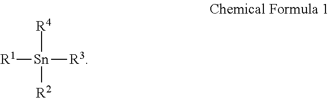
and
wherein, in Chemical Formula 1,
R¹ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted (C6 to C30 aryl) alkyl group, and L^{a}-O—R^{a} (wherein L^{a} is a substituted or unsubstituted C1 to C20 alkylene group and R^{a} is a substituted or unsubstituted C1 to C20 alkyl group),
R² to R⁴ are each independently selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted (C6 to C30 aryl) alkyl group, —OR^{b}, and —OC(═O)R^{c},
at least one selected from among R² to R⁴ are each independently selected from among —OR^{b} and —OC(═O)R^{c},
R^{b} is a substituted or unsubstituted C1 to C20 alkyl group, a substituted or unsubstituted C3 to C20 cycloalkyl group, a substituted or unsubstituted C2 to C20alkenyl group, a substituted or unsubstituted C2 to C20 alkynyl group, a substituted or unsubstituted C6 to C30 aryl group, or a combination thereof, and
R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

12. A method of forming patterns, the method comprising coating a metal-containing resist composition on a substrate;
coating the composition of claim 1 along an edge of the substrate;
drying and heating a resultant coating to form a metal-containing photoresist film on the substrate;
exposing the metal-containing photoresist film; and
developing the metal-containing photoresist film.

13. A system of forming patterns, the system comprising
means for coating a metal-containing resist composition on a substrate;
means for coating the composition of claim 1 along an edge of the substrate;
means for drying and heating a resultant coating to form a metal-containing photoresist film on the substrate;
means for exposing the metal-containing photoresist film; and
means for developing the metal-containing photoresist film.
